(19) United States
(12) Patent Application Publication
(10) Pub. No.: US 2024/0065003 A1
(43) Pub. Date: Feb. 22, 2024

(54) SEMICONDUCTOR PACKAGE AND METHOD OF MANUFACTURING THE SEMICONDUCTOR PACKAGE

(71) Applicant: SAMSUNG ELECTRONICS CO., LTD., Suwon-si (KR)

(72) Inventors: Dongkyu KIM, Suwon-si (KR); Kyounglim SUK, Suwon-si (KR); Hyeonseok LEE, Suwon-si (KR); Hyeonjeong HWANG, Suwon-si (KR)

(21) Appl. No.: 18/295,324

(22) Filed: Apr. 4, 2023

(30) Foreign Application Priority Data
Aug. 18, 2022 (KR) 10-2022-0103154

(51) Int. Cl. H10B 80/00; H01L 23/522; H01L 23/00; H01L 23/31

(52) U.S. Cl. CPC H10B 80/00; H01L 23/5226; H01L 24/16; H01L 23/3157; H01L 24/05; H01L 24/08; H01L 24/13; H01L 24/11; H01L 2224/16145; H01L 2224/0401; H01L 2224/08145; H01L 2224/13147; H01L 2224/13124; H01L 2224/13155; H01L 2224/1318; H01L 2224/13144; H01L 2224/13139; H01L 2224/13171; H01L 2224/13111; H01L 2224/13166; H01L 2224/1146

(57) ABSTRACT

A semiconductor package includes a memory chip having chip pads on a first surface thereof. A redistribution layer is formed on the first surface of the memory chip. The redistribution layer is electrically connected to the chip pads. The redistribution layer has first redistribution pads on a first surface of the redistribution layer in a first region and a plurality of second redistribution pads on the first surface of the redistribution layer in a second region thereof. A processor chip is disposed on the first region of the redistribution layer and is electrically connected to the first redistribution pads. A sealing member is disposed on the first surface of the redistribution layer and covers the processor chip. Conductive structures are on the second region and penetrate through the sealing member and extend upwardly in a vertical direction away from the second redistribution pads.

### PRIORITY STATEMENT

This application claims priority under 35 U.S.C. § 119 to Korean Patent Application No. 10-2022-0103154, filed on Aug. 18, 2022 in the Korean Intellectual Property Office, the disclosure of which is incorporated by reference in its entirety herein.

### 1. Technical Field

Embodiments of the present disclosure relate to a semiconductor package and a method of manufacturing the semiconductor package. More particularly, embodiments of the present disclosure relate to a semiconductor package including a memory semiconductor device and a method of manufacturing the same.

### 2. Discussion of Ted Art

Technologies such as artificial intelligence (AI) and machine learning (ML) require processing of relatively large amounts of data in a short time. However, when high-capacity data is simultaneously processed, a load may be applied to a memory semiconductor device. Next-generation memory semiconductors, such as Processing-in-Memory (PIM) technology in which an arithmetic function is added to a memory semiconductor device may be utilized for high-speed data processing while removing the load applied to the memory semiconductor device.

### SUMMARY

Embodiments provide a semiconductor package including a memory chip and a processor chip that provides an arithmetic function for reducing a load on the memory chip.

Embodiments provide a method of manufacturing the semiconductor package.

According to an embodiment, a semiconductor package includes a memory chip having a plurality of chip pads disposed on a first surface of the memory chip. A redistribution layer is disposed on the first surface of the memory chip. The redistribution layer is electrically connected to the plurality of chip pads. The redistribution layer has a plurality of first redistribution pads disposed on a first surface of the redistribution layer in a first region of the redistribution layer and a plurality of second redistribution pads disposed on the first surface of the redistribution layer in a second region of the redistribution layer. A processor chip is disposed on the first region of the redistribution layer and is electrically connected to the plurality of first redistribution pads. A sealing member is disposed on the first surface of the redistribution layer and covers the processor chip. A plurality of conductive structures is disposed on the second region of the redistribution layer. The plurality of conductive structures penetrates through the sealing member and extends upwardly in a vertical direction away from the plurality of second redistribution pads.

According to an embodiment, a semiconductor package includes a package substrate. A logic semiconductor device is disposed on the package substrate. A memory semiconductor device is disposed on the package substrate to be spaced apart from the logic semiconductor device. The memory semiconductor device further includes a memory chip having a plurality of chip pads disposed on a first surface of the memory chip. A redistribution layer is disposed on the first surface of the memory chip. The redistribution layer is electrically connected to the plurality of chip pads. The redistribution layer has a plurality of first redistribution pads disposed on a first surface of the redistribution layer in a first region of the redistribution layer and a plurality of second redistribution pads disposed on the first surface of the redistribution layer in a second region of the redistribution layer. A processor chip is disposed on the first region of the redistribution layer and is electrically connected to the plurality of first redistribution pads, A sealing member is disposed on the first surface of the redistribution layer and covers the processor chip. A plurality of conductive structures is disposed on the second region of the redistribution layer. The plurality of conductive structures penetrates through the sealing member and extends upwardly in a vertical direction away from the plurality of second redistribution pads.

According to an embodiment, a method of manufacturing a semiconductor package includes forming a redistribution layer having a plurality of first and second redistribution pads on a first surface of a memory chip. A plurality of conductive structures is formed that extend upwardly in a vertical direction away from the plurality of second redistribution pads processor chip is formed that is electrically connected to the plurality of first redistribution pads. A sealing member is formed that covers the plurality of conductive structures and the processor chip. A plurality of conductive bumps is formed on a distal end of the plurality of conductive structures exposed from the sealing member, respectively.

According to an embodiment, a semiconductor package may include a memory chip having a plurality of chip pads on a surface thereof, a redistribution layer formed on the surface of the memory chip, the redistribution layer electrically connected to the chip pads, the redistribution layer having a plurality of first redistribution pads in a first region of an outer surface thereof and a plurality of second redistribution pads in a second region of the outer surface thereof, a processor chip disposed on the first region of the redistribution layer and electrically connected to the plurality of first redistribution pads, a sealing member disposed on the outer surface of the redistribution layer and covering the processor chip, and a plurality of conductive structures penetrating through the sealing member and extending upwardly from the plurality of second redistribution pads.

Thus, the processor chip electrically connected to the memory chip may reduce an electrical load applied to the memory chip. Since the memory chip and the processor chip are included in one semiconductor package, space utilization may be increased. Also, since the conductive structures extend from the second redistribution pads by a size of the processor chip, a diameter and a thickness of the conductive structures may be increased. When the thickness and the diameter of the conductive structures are increased, robustness and reliability of the semiconductor package may be increased in a board level reliability (BLR) test. Accordingly, it is possible to solve a problem of weakening of adhesion due to Cu depletion occurring between the second redistribution pad and the conductive structure (Under Bump Metallurgy, UBM).

### BRIEF DESCRIPTION OF THE DRAWINGS

Embodiments of the present disclosure will be more clearly understood from the following detailed description taken in conjunction with the accompanying drawings. FIGS. 1 to 15 represent non-limiting embodiments as described herein.

FIG. 1 is a cross-sectional view illustrating a semiconductor package according to an embodiment of the present disclosure.

FIG. 2 is a cross-sectional view illustrating a memory semiconductor device in FIG. 1 according to an embodiment of the present disclosure.

FIG. 3 is a plan view illustrating the redistribution layer in FIG. 2 according to an embodiment of the present disclosure.

FIG. 4 is an enlarged cross-sectional view illustrating portion A of FIG. 2 according to an embodiment of the present disclosure.

FIGS. 5, 6 and 8-15 are cross-sectional views illustrating a method of manufacturing a semiconductor package according to embodiments of the present disclosure.

FIG. 7 is a plan view illustrating a method of manufacturing a semiconductor package in accordance with an embodiment of the present disclosure.

### DETAILED DESCRIPTION OF EMBODIMENTS

Hereinafter, embodiments will be explained in detail with reference to the accompanying drawings.

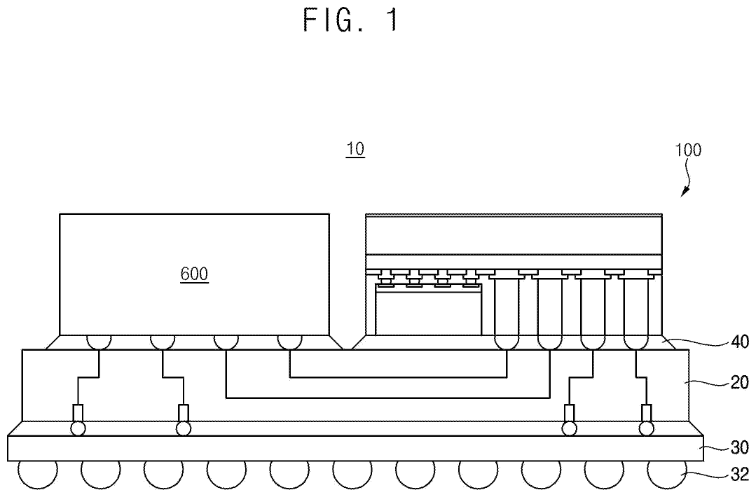

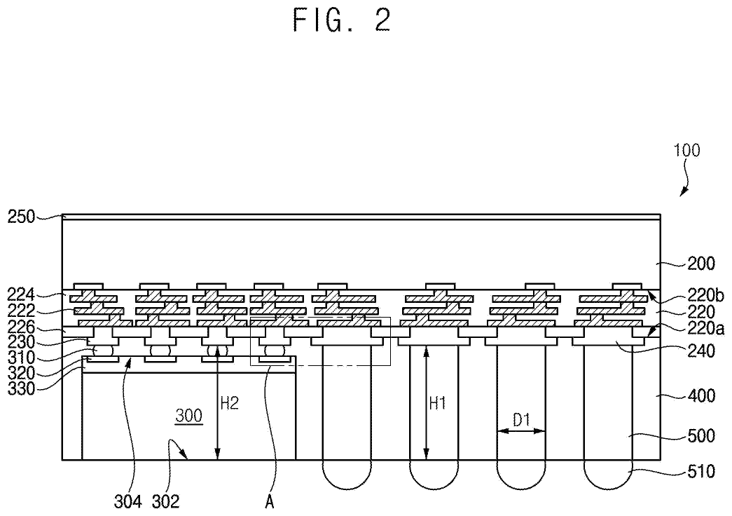

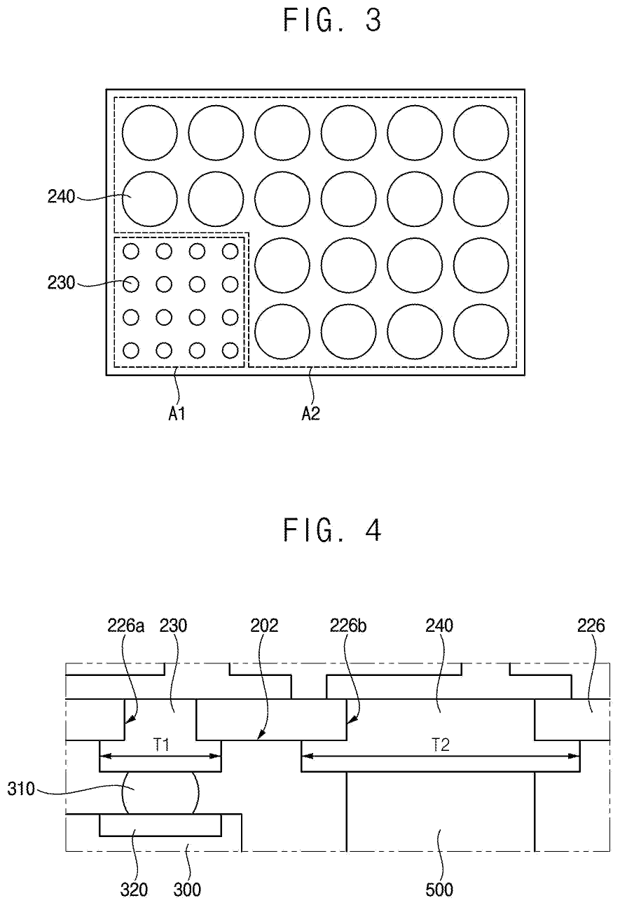

FIG. 1 is a cross-sectional view illustrating a semiconductor package in accordance with an embodiment. FIG. 2 is a cross-sectional view illustrating a memory semiconductor device in FIG. 1. FIG. 3 is a plan view illustrating a redistribution layer in FIG. 2, FIG. 4 is an enlarged cross-sectional view illustrating portion ‘A’ in FIG. 2.

Referring to FIGS. 1 to 4, a semiconductor package 10 may include an interposer 20. A memory semiconductor device 100 and a system semiconductor device 600 may be disposed on the interposer 20 to be spaced apart from each other. In addition, the semiconductor package 10 may further include a package substrate 30 on which the interposer 20 is disposed.

In an embodiment, the semiconductor package 10 may be a memory module having a stacked chip structure in which a plurality of dies (e.g., chips) are stacked. For example, in an embodiment the semiconductor package 10 may include a semiconductor memory device having a 2.5D chip structure. In this embodiment, the system semiconductor device 600 may include a logic semiconductor device. For example, the logic semiconductor device may be an ASIC as a host, such as a CPU, GPU, or SoC. The memory semiconductor device 100 may include a high bandwidth memory (HM) device, a dynamic random access memory (DRAM), and the like. However, embodiments of the present disclosure are not necessarily limited thereto. For example, in an embodiment, the semiconductor package 10 may include a semiconductor memory device having a 3D chip structure.

In an embodiment, the package substrate 30 may be a substrate having an upper surface and a lower surface facing each other. For example, in an embodiment the package substrate 30 may be a printed circuit board (PCB). The printed circuit board may be a multilayer circuit board having vias and various circuits therein.

The interposer 20 may be disposed on the package substrate 30. In an embodiment, a planar area of the interposer 20 may be less than a planar area of the package substrate 30. For example, when viewed from a plan view, the interposer 20 may be disposed in the area of the package substrate 30.

In an embodiment, the interposer 20 may be a redistribution interposer having a plurality, of redistribution wires formed therein. The memory semiconductor device 100 and the system semiconductor device 600 may be connected to each other through the redistribution wires inside the interposer 20 or may be electrically connected to the package substrate 30 through solder bumps. The redistribution interposer may provide high-density interconnection between the memory semiconductor device 100 and the system semiconductor device 600. For example, in an embodiment the interposer 20 may have an area of about 20 mm×30 mm or more.

Hereinafter, an embodiment in which the semiconductor package 10 is the semiconductor memory device having the 2.5D chip structure will be described for economy of description. However, it may be understood that the semiconductor package 10 according to embodiments of the present disclosure are not necessarily limited to the semiconductor memory device having the 2.5D chip structure.

In an embodiment, the memory semiconductor device 100 may include a memory chip 200, a redistribution layer 220 disposed on one surface (e.g., a first surface) of the memory chip 200, and a processor chip 300 mounted on the redistribution layer 220. The memory semiconductor device 100 may further include a sealing member 400 covering the first surface 220a of the redistribution layer 220 and the processor chip 300, conductive structures 500 penetrating the sealing member 400, and conductive bumps 510 respectively disposed on the conductive structures 500.

In an embodiment, the memory chip 200 may include a silicon substrate, an activation layer disposed on the silicon substrate, and a plurality of first chip pads 212 exposed from one surface of the activation layer. For example, the first chip pads 212 may be disposed on the first surface of the memory chip 200. The memory chip 200 may further include a protective layer 250 covering the silicon substrate and a through silicon via penetrating the silicon substrate in a thickness direction. For example, the protective layer 250 may be disposed on a second surface of the memory chip 200 opposite to the first surface of the memory chip 200.

For example, the memory chip 200 may include a semiconductor element such as a memory element. For example, in an embodiment the memory chip 200 may include a volatile memory device such as an SRAM device, a DRAM device, and the like, and a flash memory device, a PRAM device, and an MRAM device, and/or a nonvolatile memory device such as an RRAM device.

Circuit patterns may be disposed on one surface of the silicon substrate. The circuit pattern may include an active element or a passive element. In an embodiment, the circuit pattern may include a transistor, a diode, a resistor, a capacitor, an inductor, and the like. In an embodiment, the circuit pattern may be formed through a wafer process, such as a front-end-of-line (FEOL) process.

The protective layer 250 may be disposed on (e.g., disposed directly thereon) the upper surface of the memory chip 200 and may be formed of an insulating material to protect the silicon substrate from the external environment. In an embodiment, the protective layer 250 may be formed of an oxide film or a nitride film, or may be formed of a double layer of an oxide film and a nitride film. In an embodiment, the protective layer 250 may be formed of an oxide film, for example, a silicon oxide film (SiO2) using a high-density plasma chemical vapor deposition (HDP-CVD) process.

The through silicon via may penetrate through the silicon substrate and may be electrically connected to a multilayer wiring pattern of the redistribution layer 220 through the first chip pads 212. In an embodiment in which other semiconductor chips are mounted on the upper surface of the memory semiconductor device 100, the through silicon via may electrically connect the multilayer wiring pattern of the memory chip 200 and the other semiconductor chips.

In an embodiment, the redistribution layer 220 may be disposed on one surface (e.g., a first surface) of the memory chip 200. The redistribution layer 220 may be electrically connected to the first chip pads 212 of the memory chip 200. The redistribution layer 220 may have a first surface 220a (e.g., an outer surface) and a second surface 220b opposite to the first surface 220a. For example; in an embodiment the redistribution layer 220 may include an inter-metallic insulating layer and a passivation layer. The redistribution layer 220 may include an inter-layer dielectric (ILD) and an inter-metal dielectric (IMD).

In an embodiment, the redistribution layer 220 may be formed on the one surface (e.g., the first surface) of the memory chip by a wiring process. The multilayer wiring pattern may be formed inside the insulating layer of the redistribution layer 220. For example, in an embodiment the multilayer wiring pattern may include aluminum (Al), copper (Cu), tin (Sn), nickel (Ni), gold (Au), platinum (Pt), or an alloy thereof.

In an embodiment, the redistribution layer 220 may include a plurality of insulating films 224, redistribution wires 222 disposed in the insulating films, and first and second redistribution pads 230, 240 exposed from the insulating films 224. The insulating films 224 may include an uppermost insulating film 226 positioned on a top of the plurality of insulating films 224. The uppermost insulating film 226 may be disposed on the first surface 220a of the redistribution layer 220. The uppermost insulating film 226 may include first and second openings 226a, 226b (FIG. 4) respectively exposing the first and second redistribution pads 230, 240.

The insulating layer may include a polymer, a dielectric layer, or the like. In an embodiment, the insulating layer may be formed by a vapor deposition process, a spin coating process, or the like. The redistribution wires may include aluminum. (Al), copper (Cu), tin (Sri), nickel (Ni), gold (Au), platinum (Pt), or an alloy thereof. The redistribution wires may be formed by a plating process, an electroless plating process, a vapor deposition process, or the like.

The plurality of first redistribution pads 230 may be disposed in the uppermost insulating film 226. An upper surface of the first redistribution pad 230 may be exposed from an upper surface of the uppermost insulating film 226, such as the first surface 220a of the redistribution layer 220. The first redistribution pads 230 may be disposed in a first area A1 (e.g., a first regio of an outer surface of the redistribution layer 220. The first area A1 may be an area in which the processor chip 300 is mounted.

The uppermost insulating film 226 may have a first opening 226a exposing the upper surface of the first redistribution pad 230. The first redistribution pad 230 may be electrically connected to a solder bump 310 of the processor chip 300 through the first opening 226a. However, embodiments of the present disclosure are not necessarily limited thereto. For example, in an embodiment the first redistribution pad 230 may be electrically connected to the second chip pad 320 of the processor chip 300 by direct bonding.

The plurality of second redistribution pads 240 may be disposed in the uppermost insulating film 226. The upper surface of the second redistribution pad 240 may be exposed from an upper surface of the uppermost insulating film 226, such as the first surface 220a of the redistribution layer 220. The second redistribution pads 240 may be disposed in a second area A2 of the outer surface of the redistribution layer 220. The second area A2 (e.g., a second region) may be an area in which the conductive structures 500 are disposed. In an embodiment, the conductive structures 500 may not be disposed in the first area A1. As shown in FIG. 3, the first area A1 and the second area A2 may be different areas that do not overlap each other.

The uppermost insulating film 226 may have the second opening 226b exposing the upper surface of the second redistribution pad 240. The second redistribution pad 240 may be bonded to and electrically connected to the conductive structure 500.

The first redistribution pad 230 may have a first width T1. The second redistribution pad 240 may have a second width T2. In an embodiment, the second width T2 of the second redistribution pad 240 may be greater than the first width T1 of the first redistribution pad 230. The second redistribution pad 240 may strengthen coupling with the conductive structure 500 through the second width T2 that is greater than the first width T1 of the first redistribution pad 230.

For example, in an embodiment, the first width T1 of the first redistribution pad 230 may be in a range of about 100 μm to about 500 μm. The second width T2 of the second redistribution pad 240 may be within a range of about 100 μm to about 500 μm.

The redistribution wire 222 of the redistribution layer 220 may be disposed on the uppermost insulating film 226 and may directly contact the first redistribution pad 230 through the first opening 226a. The redistribution wire 222 may be disposed on the uppermost insulating film 226 and may directly contact the second redistribution pad 240 through the second opening 226b. The redistribution wire 222 may electrically connect the first and second redistribution pads 230, 240 to the circuit patterns.

In an embodiment, the conductive structures 500 may be respectively disposed on the second redistribution pads 240. The conductive structures 500 may extend in a vertical direction from the second redistribution pads 240. For example, in an embodiment the conductive structures 500 may extend upwardly in the vertical direction away from the second redistribution pads 240. The vertical direction may be the same as the direction in which the processor chip 300 is mounted on the redistribution layer 220 as described later. One end of the conductive structures 500 may be connected to the second redistribution pads 240, and the other end opposite to the one end of the conductive structures 500 may be exposed from the sealing member 400.

In an embodiment, the conductive structures 500 may be arranged to surround an outside of the processor chip 300, Therefore, the conductive structures 500 may be arranged to be outside the processor chip 300. The conductive structures 500 may support a lower surface of the redistribution layer 220. In an embodiment, the conductive structure 500 may have a diameter and height which prevents a problem of weakening adhesion due to copper depletion occurring in relation to the second redistribution pad 240.

In an embodiment, the conductive structures 500 may include aluminum (Al), copper (Cu), or the like, and may be formed through pulse plating or DC plating. The conductive structures 500 may be formed of a conductive material, for example, copper (Cu), aluminum (A gold (Au), solder, or the like. However, embodiments of the present disclosure are not necessarily limited thereto and the conductive material of the conductive structures 500 may vary.

For example, the conductive structure 500 may have a first height and a first diameter D1. In an embodiment, the first height H1 of the conductive structure 500 may be in a range of about 100 μn to about 400 μm. The first diameter D1 of the conductive structure 500 may be in a range of about 100 μm to about 400 μm.

In an embodiment, the conductive bumps 510 may be respectively disposed on the conductive structures 500. The conductive bumps 510 may be disposed on the conductive structure 500 to mount the memory semiconductor device 100 on the interposer 20, the package substrate 30, or the like. For example, the conductive bump 510 may include a solder ball.

In an embodiment, the conductive bumps 510 may include aluminum (Al), copper (Cu), or the like, and may be formed through pulse plating or DC plating. The conductive bump 510 may be formed of the conductive material, for example, copper (Cu), aluminum (Al), gold (Au), solder, or the like. However, the material of the conductive bump 510 is not necessarily limited thereto. For example, in some embodiments the conductive bumps 510 may include micro bumps (uBump).

In an embodiment, the processor chip 300 may be disposed on the redistribution layer 220. The processor chip 300 may include an upper surface 302 and a lower surface 304 opposite to each other. The lower surface 304 (e.g., a first surface) of the processor chip 300 may include the second chip pad 320 may be disposed to face the first surface 220a of the redistribution layer 220. The processor chip 300 may be electrically connected to the first redistribution pad 230 of the redistribution layer 220. The processor chip 300 may be mounted on the redistribution layer 220 to form the high-density interconnection with the emory chip 200.

For example, the processor chip 300 may include a semiconductor element such as a logic element. In an embodiment, the processor chip 300 may include the logic element such as a central processing unit (CPU), a graphics processing unit (GPU), a micro processing unit (MPU), a micro controller unit (MCU), an application processor (AP).

The processor chip 300 may be electrically connected to the memory chip 200 to reduce an electrical load applied to the memory chip 200. In an embodiment, the processor chip 300 may provide an arithmetic function to the memory chip 200. A planar area of the processor chip 300 may be less than a planar area of the memory chip 200. For example, when viewed from the plan view, the processor chip 300 may be disposed in the area of the memory chip 200.

The processor chip 300 may include a plurality of second chip pads 320 and a plurality of solder bumps 310 respectively disposed on the second chip pads 320. The second chip pads 320 may be arranged to be exposed from the lower surface 304 of the processor chip 300. The processor chip 300 may be disposed on the redistribution layer 220 via the solder bumps 310.

In an embodiment, the processor chip 300 may be mounted on the redistribution layer 220 by a flip chip bonding method. In this embodiment, the processor chip 300 may be mounted such that an activation surface on which the second chip pads 320 are formed faces the redistribution layer 220, The second chip pads 320 of the processor chip 300 may be electrically connected to the first redistribution pads 230 of the redistribution layer 220 by solder bumps 310 as conductive mediators. For example, in an embodiment the solder bumps 310 may include micro bumps (μBump).

The processor chip 300 may include a lower insulating film 330 disposed on the lower surface 304. The lower insulating film 330 of the processor chip 300 and the insulating film 224 of the redistribution layer 220 may be directly bonded to each other. Accordingly, the first redistribution pad 230 and the second chip pad 320 may be bonded to each other between the redistribution layer 220 and the processor chip 300 by Cu—Cu Hybrid Bonding (e.g., pad to pad direct bonding).

The upper surface 302 of the processor chip 300 may have a second height H2; from the redistribution layer 220. In an embodiment, the second height H2 of the processor chip 300 may be less than or equal to the first height H1 of the conductive structures 500. Since the second height H2 of the processor chip 300 is less than or equal to the first height H1 of the conductive structures 500, the conductive bumps 510 may be disposed on one end (e.g., a distal end) of the conductive structures 500 that is opposite to a proximal end of the conductive structures 500 that directly contacts the second redistribution pads 240. The conductive bumps 510 may protrude from the memory semiconductor device 100 on the conductive structure 500.

In an embodiment, the sealing member 400 may be disposed on the first surface 220a of the redistribution layer 220. The sealing member 400 may cover an outer surface of each of the conductive structures 500 and the processor chip 300. The one end (e.g., an upper end) of the conductive structure 500 may be exposed from the sealing member 400 to be connected to the conductive bump 510. The upper surface 302 of the processor chip 300 may be exposed by the sealing member 400. For example, in an embodiment the sealing member may include an epoxy mold compound (EMC). However, embodiments of the present disclosure are not necessarily limited thereto.

Although one memory semiconductor device 100 and one system semiconductor device 600 are illustrated in FIGS. 1, 4, embodiments of the present disclosure are not necessarily limited thereto. For example, in an embodiment the memory semiconductor device 100 may include a buffer die and a plurality of memory dies (e.g., chips) sequentially stacked on the buffer die.

In addition, the semiconductor package 10 may further include an adhesive 40 that is underfilled between the interposer 20 and the memory semiconductor device 100. For example, in an embodiment the adhesive 40 may include an epoxy material to reinforce a gap between the interposer 20 and the memory semiconductor device 100. The adhesive 40 may be underfilled between the system semiconductor device 600 and the interposer 20. The adhesive 40 may also be underfilled between the interposer 20 and the package substrate 30.

In an embodiment, external connection pads may be formed on the lower surface of the package substrate 30, and external connection members 32 may be disposed on the external connection pads for electrical connection with an external device. For example, the external connection member 32 may be the solder ball. However, embodiments of the present disclosure are not necessarily limited thereto. The semiconductor package 10 may be mounted on a module substrate via the solder balls to constitute a memory module.

Although only some substrates, some bonding pads, and some wirings are illustrated in the drawings, it may be understood that the number and arrangement of the substrates, the bonding pads, and the wirings are not necessarily limited thereto. Since the wirings as well as the substrates are well known in the art to which the present disclosure pertains, illustration and description concerning the above elements may be omitted for economy of description.

As described above, an electrical load applied to the memory chip 200 may be reduced by the processor chip 300 that is electrically connected to the memory chip 200. Since the memory chip 200 and the processor chip 300 are included in one memory semiconductor device 100, space utilization may be increased.

Also, since the conductive structures 500 extend from the second redistribution pads 240 by a size of the processor chip 300, a diameter and a thickness of the conductive structures 500 may be increased. In an embodiment in which the thickness and the diameter of the conductive structures 500 are increased, rigidity and reliability of the semiconductor package may be increased in a board level reliability (BLR) test. Accordingly, a weakening of adhesion due to Cu depletion occurring between the second redistribution pad 240 and the conductive structure 500 (Under Bump Metallurgy, UBM) may be reduced or eliminated.

Hereinafter, a method of manufacturing the semiconductor package in FIG. 1 will be explained.

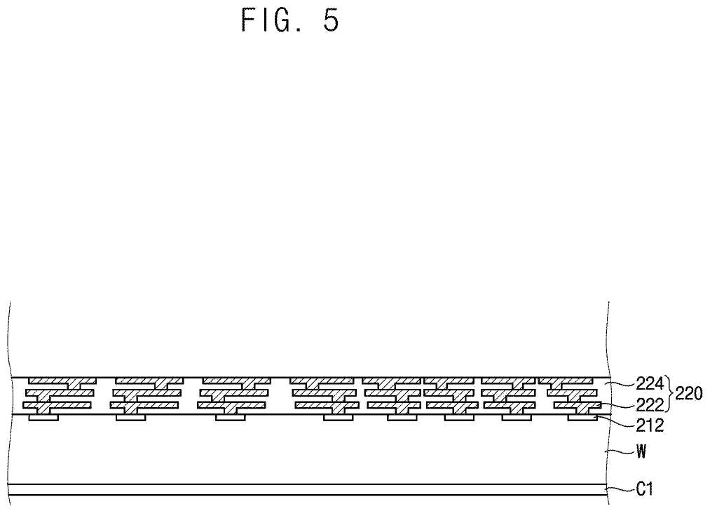

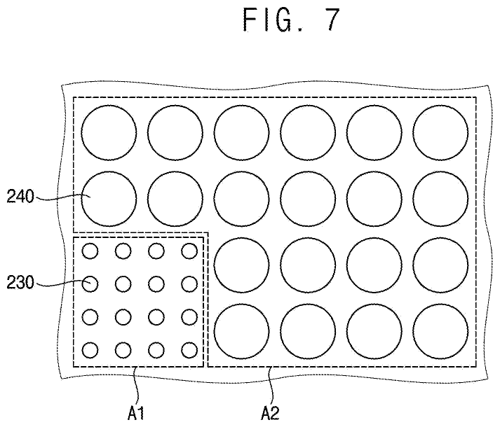

FIGS. 5 to 15 are views illustrating a method of manufacturing a semiconductor package in accordance with embodiments. More specifically, FIGS. 5, 6, 8-15 are cross-sectional views illustrating a method of manufacturing a semiconductor package in accordance with embodiments. FIG. 7 is a plan view illustrating a method of manufacturing a semiconductor package in accordance with embodiments.

Referring to FIGS. 5 to 8, a redistribution layer 220 having first and second redistribution pads 230, 240 may be formed on a silicon wafer W having a plurality of memory chips 200. In an embodiment, the silicon wafer W may be formed on a carrier substrate Cl, and the redistribution layer 220 having a redistribution wire 222 and an insulating film 224 may be formed on the silicon wafer W. The silicon wafer W inlay be a base wafer for forming the plurality of memory chips 200.

In an embodiment, circuit patterns may be formed on one surface of the silicon wafer W. The circuit patterns may be formed to be electrically connected to first chip pads 212. In an embodiment, the circuit pattern may include an active element or a passive element. For example, the circuit pattern may include a transistor, a diode, a resistor, a capacitor, an inductor, and the like. In an embodiment, the circuit pattern may be formed through a wafer process called a front-end-of-line (FEOL) process.

The circuit patterns may be electronic circuits for driving the memory chip 200. For example, the memory chip 200 may include a semiconductor element such as a memory element. For example, in an embodiment, the memory chip 200 may include a volatile memory device such as an SRAM device, a DRAM device, and the like, and a flash memory device, a PRAM device, and/or an MRAM device, a nonvolatile memory device such as an RRAM device.

The redistribution layer 220 may be formed on one surface of the silicon wafer W by a wiring process. The redistribution layer 220 may be electrically connected to the first chip pads 212 formed on one surface of the silicon wafer W. The redistribution layer 220 may include a plurality of insulating films 224 and redistribution wires 222 provided in the insulating films 224.

The insulating film 224 may include a polymer, a dielectric film, or the like. For example, in an embodiment the insulating film 224 may include polyimide (PI), lead oxide (PbO), polyhydroxystyrene (PHS), novolac (NOVOLAC), or the like. In an embodiment, the insulating film 224 may be formed by a vapor deposition process, a spin coating process, or the like. However, embodiments of the present disclosure are not necessarily limited thereto.

In an embodiment, the redistribution wires may include aluminum (Al), copper (Cu), tin (Sri), nickel (Ni), gold (Au), platinum (Pt), or an alloy thereof. In an embodiment, the redistribution wires may be formed by a plating process, an electroless plating process, a vapor deposition process, or the like. However, embodiments of the present disclosure are not necessarily limited thereto.

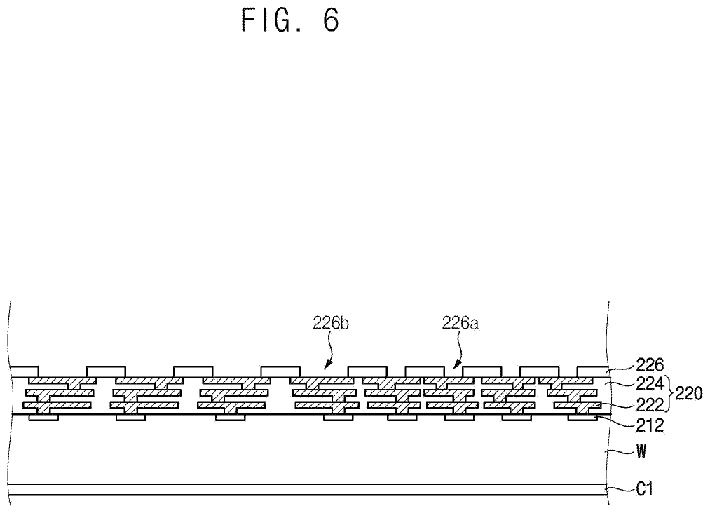

As illustrated in FIG. 6, an uppermost insulating film 226 may be formed on one surface of the redistribution layer 220. The uppermost insulating film 226 may be formed to cover the redistribution wire 222. The uppermost insulating film 226 may be patterned to form first and second openings 226a, 226b having different sizes.

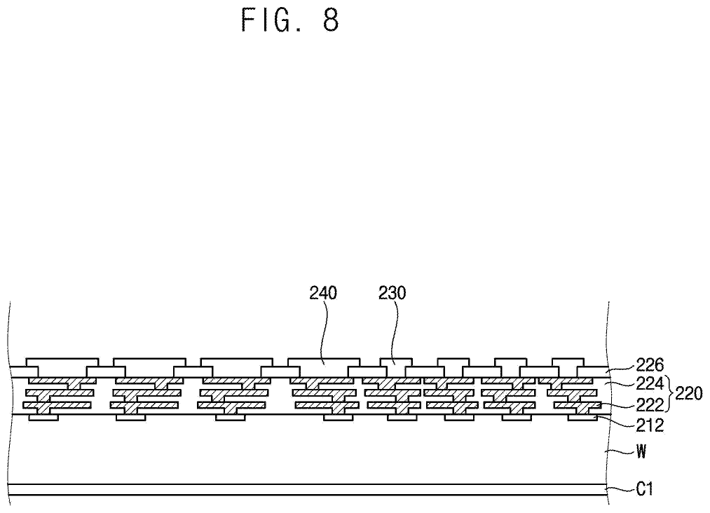

As illustrated in FIGS. 7 and 8, first and second redistribution pads 230, 240 electrically connected to the redistribution wire 222 may be formed on the uppermost insulating film 226.

In an embodiment, a first plating process may be performed on the first openings 226a to form first redistribution pads 230, and a second plating process may be performed on the second openings 226b to perform a second redistribution process. The second redistribution pads 240 may be formed. The first redistribution pads 230 may be formed in a first area A1 of an outer surface of the redistribution layer 220. The first area A1 may be an area in which the processor chip 300 is mounted. The second redistribution pads 240 may be formed in a second area A2 of the outer surface of the redistribution layer 220. The first area A1 and the second area A2 may be different areas.

A photoresist layer may be formed on the redistribution wire 222 and the uppermost insulating film 226, and an exposure process may be performed on the photoresist layer to form a photoresist pattern exposing redistribution pad regions. A plating process may then be performed on the photoresist pattern to form first and second redistribution pads 230, 240, In an embodiment, the plating process may include an electrolytic plating process or an electroless plating process.

For example, a first width T1 of the first redistribution pad 230 may be in a range of about 100 μm to about 500 μm. A second width T2 of the second redistribution pad 240 may be in a range of about 100 μm to about 500 μm. For example, in an embodiment the first and second redistribution pads 230, 240 may include nickel (Ni), antimony (Sb), bismuth (Bi), zinc (Zn), indium (In), palladium (Pd), Platinum (Pt), aluminum (Al), copper (Cu), molybdenum (Mo), titanium (Ti), gold (Au), silver (Ag), chromium (Cr), tin (Sn) or alloys thereof.

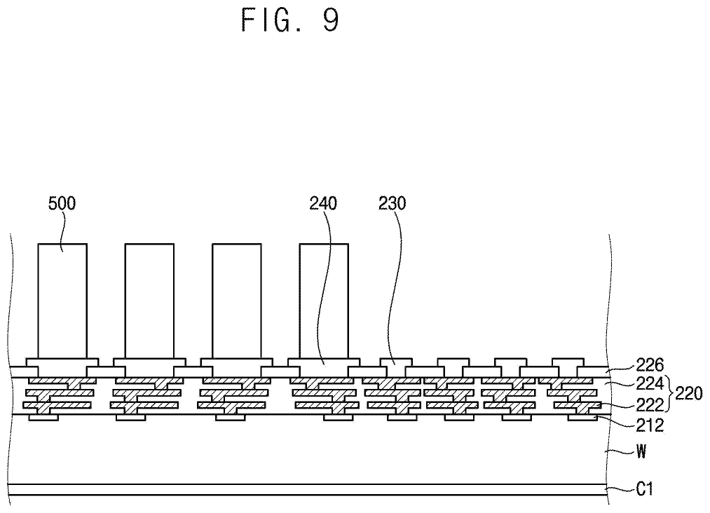

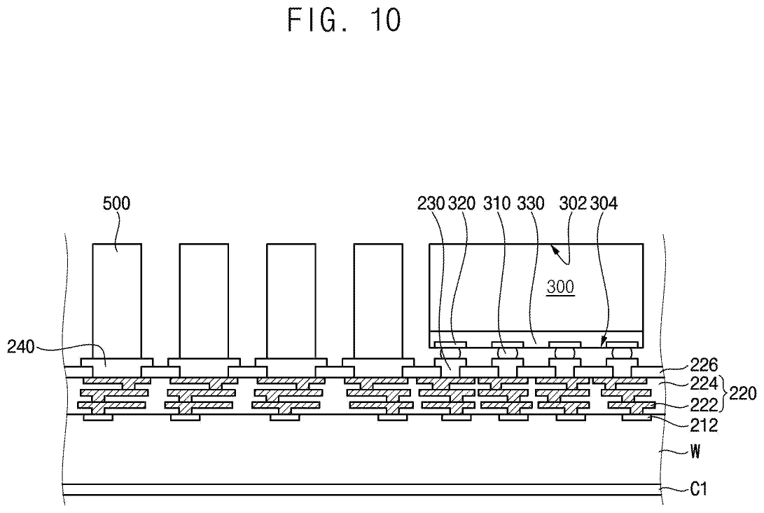

Referring to FIG. 9, a plurality of conductive structures 500 may be formed on the second redistribution pads 240. For example, in an embodiment the conductive structure 500 may have a pillar shape, a bump shape, or the like. For example, the conductive structure 500 may be formed by a plating process, an electroless plating process, a vapor deposition process, or the like. However, embodiments of the present disclosure are not necessarily limited thereto.

The conductive structures 500 may be formed to have a first height H1 (FIG. 2) from the second redistribution pad 240 of the redistribution layer 220. The conductive structures 500 may be formed to have a first diameter D1 (FIG. 2). In an embodiment, the first height H1 of the conductive structure 500 may be in a range of about 100 μm to about 400 μm. The first diameter D1 of the conductive structure 500 may be in a range of about 100 μm to about 400 μm.

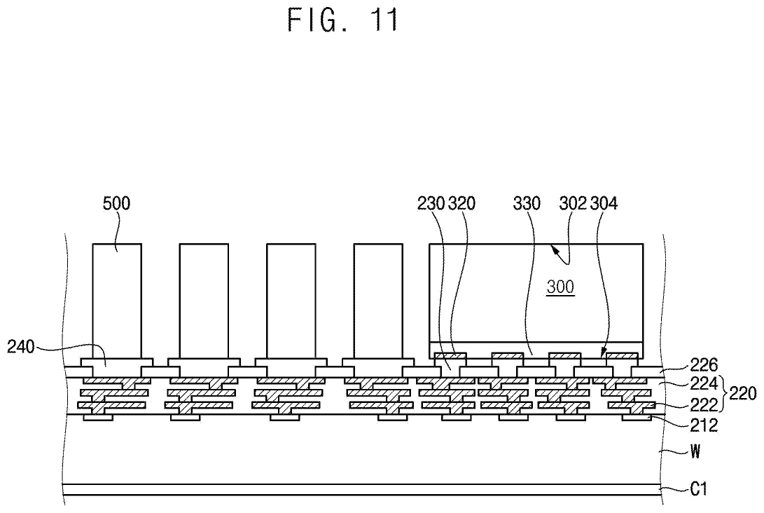

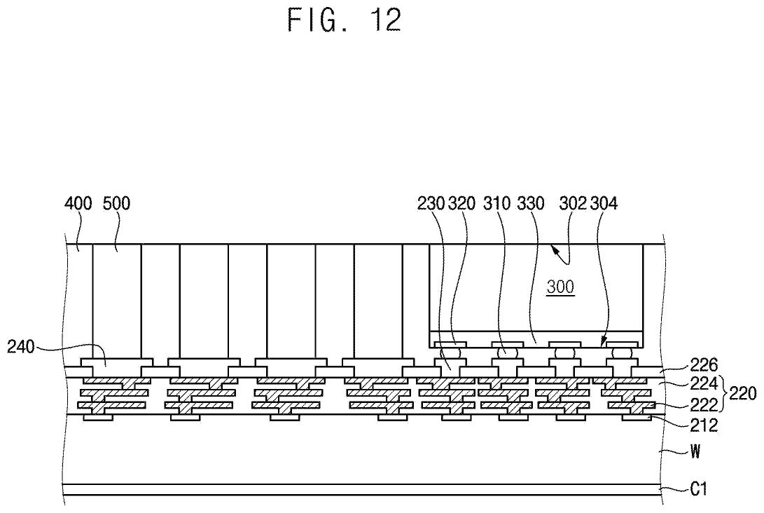

Referring to FIGS. 10 and 11, the processor chip 300 may be mounted on the redistribution layer 220. The processor chip 300 may be mounted on the redistribution layer 220 to form a high-density interconnection with the memory chip 200.

The processor chip 300 may include an upper surface 302 and a lower surface 304 opposite to each other. The lower surface 304 of the processor chip 300 may be disposed to face the redistribution layer 220. The processor chip 300 may be electrically connected to the first redistribution pad 230 of the redistribution layer 220.

In an embodiment, the processor chip 300 may be electrically connected to the memory chip 200 to reduce an electrical load applied to the memory chip 200. For example, the processor chip 300 may provide an arithmetic function to the memory chip 200. A planar area of the processor chip 300 may be less than a planar area of the memory chip 200. When viewed from a plan view, the processor chip 300 may be disposed in the area of the memory chip 200.

For example, the processor chip 300 may include a semiconductor element such as a logic element. In an embodiment, the processor chip 300 may include the logic element such as a central processing unit (CPU), a graphics processing unit (GPU), a micro processing unit (MPU), a micro control unit (MeV), an application processor (AP).

As illustrated in FIG. 10, the processor chip 300 may be mounted on the redistribution layer 220 by a flip chip bonding method. In this embodiment, the processor chip 300 may be mounted on the redistribution layer 220 such that an activation surface on which second chip pads 320 are formed faces the redistribution layer 220. The second chip pads 320 of the processor chip 300 may be electrically connected to the first redistribution pads 230 of the redistribution layer 220 by solder bumps 310 as conductive bumps. For example, in an embodiment the solder bumps 310 may include micro bumps (uBump). However, embodiments of the present disclosure are not necessarily limited thereto.

For example, in an embodiment shown in FIG. 11, the second chip pad 320 of the processor chip 300 and the second redistribution pad 240 of the redistribution layer 220 may directly contact each other. A front surface of the processor chip 300 and a front surface of the memory chip 200 may be bonded to face each other. The processor chip 300 may include a lower insulating film 330 provided on the lower surface 304. The lower insulating film 330 of the processor chip 300 and the insulating film 224 of the redistribution layer 220 may be directly bonded to each other. In an embodiment in which the processor chip 300 and the redistribution layer 220 are bonded to each other by wafer-to-die bonding, the first redistribution pad 230 and the second chip pad 320 may be bonded to each other between the redistribution layer 220 and the processor chip 300 by Cu—Cu Hybrid Bonding (e.g., pad to pad direct bonding).

For example, the upper surface 302 of the processor chip 300 may be formed to have a second height H2 from the redistribution layer 220. The second height H2 of the processor chip 300 may be less than or equal to the first height H₁ of the conductive structures 500. Since the second height H2 of the processor chip 300 is less than or equal to the first height H₁ of the conductive structures 500, conductive bumps 510 may be formed to protrude from a memory semiconductor device 100 on the conductive structure 500.

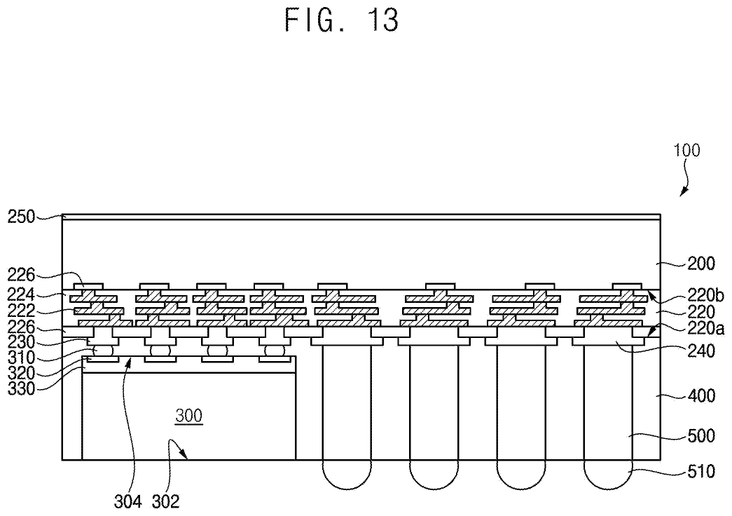

Referring to FIG. 12, a sealing member 400 may be formed to cover the processor chip 300, the redistribution layer 220, and the conductive structures 500 in an overmold structure.

In an embodiment, an upper surface of the sealing member 400 may be polished in parallel to expose an upper surface of the conductive structures 500. For example, the upper surface of the sealing member 400 may be polished through a grinding process. 0.1n the grinding process, the sealing member 400 may be polished to expose the upper surface of the conductive structure 500 and the upper surface of the processor chip 300. For example, in an embodiment the sealing member 400 may include an epoxy mold compound (EMC).

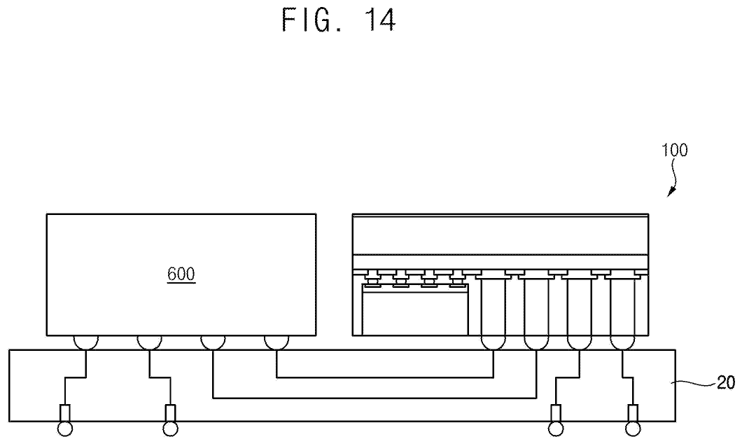

Referring to FIG. 13, conductive bumps 510 are respectively formed on the conductive structures 500, and the memory semiconductor device 100 may be formed by cutting the silicon wafer W, the redistribution layer 220, and the sealing member 400.

A photoresist pattern having openings exposing a region of the conductive structure 500 may be formed on the upper surface of the sealing member 400, and conductive bumps 510 may be formed on the conductive structure 500.

In an embodiment, after the openings of the photoresist pattern are filled with a conductive material, the photoresist pattern may be removed and a reflow process may be performed to form the conductive bumps 510. For example, the conductive bumps 510 may be formed by a plating process. However, embodiments of the present disclosure are not necessarily limited thereto. For example, in an embodiment the conductive bumps 510 may be formed by a screen printing method, a deposition method, or the like. For example, the conductive bump 510 may include a C4 bump.

A protective layer 250 may be formed on one surface of the silicon wafer W. The protective layer 250 may be formed of an insulating material to protect the substrate 210 formed by shielding the silicon wafer W from the external environment. In an embodiment, the protective layer 250 may be formed of an oxide film or a nitride film, or may be formed of a double layer of an oxide film and a nitride film. The protective layer 250 may be formed of an oxide film, for example, a silicon oxide film (SiO2) through a high-density plasma chemical vapor deposition (FDP-CVD) process.

The memory semiconductor device 100 may be formed by cutting the silicon wafer W, the redistribution layer 220, and the sealing member 400 along a scribe lane region SR surrounding a chip region DA. The scribe lane region SR may be a portion cut by a sawing process at a wafer level.

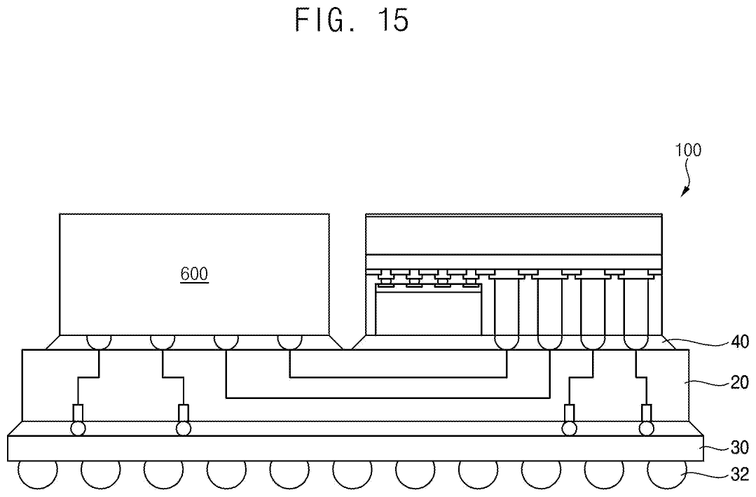

Referring to FIGS. 14 and 15, the memory semiconductor device 100 may be mounted on the interposer 20 through conductive bumps 510. A system semiconductor device 600 may be mounted on the interposer 20 to be electrically connected to the memory semiconductor device 100 through the interposer 20.

In an embodiment, the system semiconductor device 600 and the memory semiconductor device 100 may be attached to the interposer 20 by a thermal compression process. The interposer 20 may be attached to the package substrate 30 by the thermal compression process.

An adhesive 40 may then be underfilled between the interposer 20 and the package substrate 30. The adhesive 40 may be underfilled between the memory semiconductor device 100 and the interposer 20. The adhesive 40 may be underfilled between the system semiconductor device 600 and the interposer 20. The adhesive 40 may reinforce gaps between each of the interposer 20, the package substrate 30, the memory semiconductor device 100, and the system semiconductor device 600.

The semiconductor package 10 of FIG. 1 may then be completed by forming external connection members 32 such as solder balls on external connection pads on the lower surface of the package substrate 30.

The foregoing is illustrative of embodiments of the present disclosure and is not to be construed as limiting thereof. Although a few embodiments have been described, those skilled in the art will readily appreciate that many modifications are possible in embodiments without materially departing from the teachings and advantages of the present disclosure.

What is claimed is:

1. A semiconductor package, comprising:
a memory chip having a plurality of chip pads disposed on a first surface of the memory chip;
a redistribution layer disposed on the first surface of the memory chip, the redistribution layer electrically connected to the plurality of chip pads, the redistribution layer having a plurality of first redistribution pads disposed on a first surface of the redistribution layer in a first region of the redistribution layer and a plurality of second redistribution pads disposed on the first surface of the redistribution layer in a second region of the redistribution layer;
a processor chip disposed on the first region of the redistribution layer and electrically connected to the plurality of first redistribution pads;
a sealing member disposed on the first surface of the redistribution layer and covering the processor chip; and
a plurality of conductive structures disposed on the second region of the redistribution layer, the plurality of conductive structures penetrating through the sealing member and extending upwardly in a vertical direction away from the plurality of second redistribution pads.

2. The semiconductor package of claim 1, wherein the processor chip includes:
a plurality of second chip pads disposed on a first surface of the processor chip facing the first surface of the redistribution layer; and
a plurality of solder bumps respectively disposed on the plurality of second chip pads and respectively bonded to the plurality of first redistribution pads.

3. The semiconductor package of claim 1, wherein the processor chip includes a plurality of second chip pads disposed on a first surface of the processor chip facing the first surface of the redistribution layer, the plurality of second chip pads respectively bonded to the plurality of first redistribution pads.

4. The semiconductor package of claim 1, wherein:
a height of each of the plurality of conductive structures is in a range of about 100 μm to about 400 μm; and
a diameter of each of the plurality of conductive structure is in a range of about 100 μm to about 400 μm.

5. The semiconductor package of claim 1, wherein:
each of the plurality of conductive structures has a first height from the first surface of the redistribution layer to a distal end of each of the plurality of conductive structures; and
an upper surface of the processor chip has a second height less than or equal to the first height from the first surface of the redistribution layer.

6. The semiconductor package of claim 1, further comprising:
a plurality of conductive bumps respectively disposed at a distal end of the plurality of conductive structures exposed from the sealing member.

7. The semiconductor package of claim 1, wherein the plurality of conductive structures is arranged in the sealing member to be outside the processor chip.

8. The semiconductor package of claim 1, wherein a width of each of the plurality of first and second redistribution pads is in a range of about 100 μm to about 500 μm.

9. The semiconductor package of claim 1, wherein the plurality of conductive structures includes at least one of copper (Cu), aluminum (Al), tungsten (W), nickel (Ni), molybdenum (Mo), gold (Au), silver (Ag), chromium (Cr), tin (Sn) and titanium (Ti).

10. The semiconductor package of claim 1, wherein:
the processor chip includes at least one of Central Processing Unit (CPU), Graphics Processing Unit (GPU), Micro Processing Unit (MPU), Micro Controller Unit (′ICU), Application Processor (AP); and
the memory chip includes at least one of SRAM, DRAM, flash memory, PRAM, MRAM, RRAM.

11. A semiconductor package, comprising:
a package substrate;
a logic semiconductor device disposed on the package substrate; and
a memory semiconductor device disposed on the package substrate to be spaced apart from the logic semiconductor device,
wherein the memory semiconductor device further includes,
a memory chip having a plurality of chip pads disposed on a first surface of the memory chip;
a redistribution layer disposed on the first surface of the memory chip, the redistribution layer electrically connected to the plurality of chip pads, the redistribution layer having a plurality of first redistribution pads disposed on a first surface of the redistribution layer in a first region of the redistribution layer and a plurality of second redistribution pads disposed on the first surface of the redistribution layer in a second region of the redistribution layer;
a processor chip disposed on the first region of the redistribution layer and electrically connected to the plurality of first redistribution pads;
a sealing member disposed on the first surface of the redistribution layer and covering the processor chip; and
a plurality of conductive structures disposed on the second region of the redistribution layer, the plurality of conductive structures penetrating through the sealing member and extending upwardly in a vertical direction away from the plurality of second redistribution pads.

12. The semiconductor package of claim 11, wherein the processor chip includes:
a plurality of second chip pads disposed on a first surface of the processor chip facing the first surface of the redistribution layer; and
a plurality of solder bumps respectively disposed on the plurality of second chip pads and respectively bonded to the plurality of first redistribution pads.

13. The semiconductor package of claim 11, wherein the processor chip includes a plurality of second chip pads disposed on a first surface of the processor chip facing the first surface of the redistribution layer, the plurality of second chip pads respectively bonded to the plurality of first redistribution pads.

14. The semiconductor package of claim 11, wherein:
a height of each of the plurality of conductive structures is in a range of about 100 μm to about 400 μm; and
a diameter of each of the plurality of conductive structures is in a range of about 100 μm to about 400 μm.

15. The semiconductor package of claim 11, wherein:
each of the plurality of conductive structures has a first height from the first surface of the redistribution layer to a distal end of each of the plurality of conductive structures; and
an upper surface of the processor chip has a second height less than or equal to the first height from the first surface of the redistribution layer.

16. The semiconductor package of claim 11, wherein the memory semiconductor device further includes a plurality of conductive bumps respectively disposed at a distal end of the plurality of conductive structures exposed from the sealing member.

17. The semiconductor package of claim 11, wherein the plurality of conductive structures are arranged in the sealing member to be outside the processor chip.

18. The semiconductor package of claim 11, wherein a width of each of the plurality of first and second redistribution pads is in a range of about 100 μm to about 500 μm.

19. The semiconductor package of claim 11, wherein:
each of the logic semiconductor device and the processor chip includes at least one of Central Processing Unit (CPU), Graphics Processing Unit (GPU), Micro Processing Unit (WU), Micro Controller Unit (MCU) and Application Processor (AP); and
the memory chip includes at least one of SRAM, DRAM, flash memory, PRAM, MRAM, RRAM.

20. A method of manufacturing a semiconductor package, comprising:
forming a redistribution layer having a plurality of first and second redistribution pads on a first surface of a memory chip;
forming a plurality of conductive structures that extend upwardly in a vertical direction away from the plurality of second redistribution pads;
providing a processor chip that is electrically connected to the plurality of first redistribution pads;
forming a sealing member that covers the plurality of conductive structures and the processor chip; and
forming a plurality of conductive bumps on a distal end of the plurality of conductive structures exposed from the sealing member, respectively.
